(19) United States
(12) Patent Application Publication
(10) Pub. No.: US 2008/0272424 A1
(43) Pub. Date: Nov. 6, 2008

(54) Nonvolatile Memory Device Having Fast Erase Speed And Improved Retention Characteristics And Method For Fabricating The Same

(75) Inventors: Yong Top Kim, Seoul (KR); Hong Seon Yang, Seoul (KR); Tae Yoon Kim, Seoul (KR); Yong Soo Kim, Suwon-Si (KR); Seung Ryong Lee, Seoul (KR); Moon Sig Joo, Icheon-Si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-Si (KR)

(21) Appl. No.: 11/940,647

(22) Filed: Nov. 15, 2007

(30) Foreign Application Priority Data
May 3, 2007 (KR) 10-2007-0042845

(51) Int. Cl. H01L 27/00; H01L 21/8246

(52) U.S. Cl. 257/321; 438/585; 257/E21.662; 257/E27.075

(57) ABSTRACT

Disclosed herein is a nonvolatile memory device that includes a substrate, a tunneling layer over the substrate, a charge trapping layer over the tunneling layer, an insulating layer for improving retention characteristics over the charge trapping layer, a blocking layer over the insulating layer, and a control gate electrode over the blocking layer. Also disclosed herein is a method of making the device.

### CROSS-REFERENCE TO RELATED APPLICATION

Priority to Korean patent application number 10-2007-0042845, filed on May 3, 2007, the disclosure of which is incorporated by reference in its entirety, is claimed.

### BACKGROUND OF THE INVENTION

1. Field of the Invention

The invention relates to a nonvolatile memory device, and more particularly to a nonvolatile memory device having a fast erase speed and improved retention characteristics, and a method for fabricating the same.

2. Brief Description of Related Technology

Generally, semiconductor memory devices, which are used to store data, may be classified into volatile and nonvolatile types. In volatile memory devices, stored data disappears when the supply of electric power is cut off. In nonvolatile memory devices, however, stored data is retained even when the supply of electric power is cut off. Accordingly, nonvolatile memory devices are widely used in mobile phone systems, memory cards for storing music and/or image data, and other application appliances which may encounter situations in which it is impossible to always use electric power, the supply of electric power is often cut off, or it is necessary to use a reduced amount of electric power.

Typically, the cell transistor of a nonvolatile memory device has a stacked floating gate structure. The stacked floating gate structure includes a gate insulating layer, a floating gate electrode, an inter-gate insulating layer, and a control gate electrode, all of which are stacked, in the recited order, over a channel region of the cell transistor. However, this stacked floating gate structure has a limitation on an increase in the integration degree of the device because there may be various interferences caused by the increased integration degree. To this end, there is increased interest in a nonvolatile memory device with a charge trapping layer.

Generally, such a nonvolatile memory device has a stacked structure including a substrate formed therein with a channel region, a tunneling layer, a charge trapping layer, a blocking layer, and a control gate electrode, all of which are stacked in the recited order. In order to suppress backward tunneling of electrons into the control gate electrode, a structure including an insulating layer having a high dielectric constant (high-k) as the blocking layer, and a metal gate having a sufficiently high work function as the control gate electrode has been proposed. Such a structure is often referred to as a “metal-alumina-nitride-oxide-silicon (MANOS) structure”.

FIG. 1 is a sectional view illustrating a nonvolatile memory device having a general MANOS structure. Referring to FIG. 1, a tunnel insulating layer 110 is disposed over a substrate 100, such as a silicon substrate, as a tunneling layer. Impurity regions 102, such as source/drain regions, are disposed in the semiconductor substrate 100 such that they are spaced apart from each other by a certain distance. A channel region 104 is positioned between the impurity regions 102. The tunnel insulating layer 110 is positioned over the channel region 104. A silicon nitride layer 120 is disposed over the tunnel insulating layer 110, as a charge trapping layer. An aluminum oxide (Al₂O₃) layer 130 is disposed over the silicon nitride layer 120, as a blocking layer. A metal electrode layer 140 is disposed over the aluminum oxide (Al₂O₃) layer 130, as a control gate electrode.

Hereinafter, operation of the nonvolatile memory device having the above-mentioned structure will be described. When the metal electrode layer 140 has been positively electrified and an appropriate bias is applied to the impurity regions 102, hot electrons from the substrate 100 are trapped into trap sites of the silicon nitride layer 120 functioning as the charge trapping layer. This operation is a programming operation. On the other hand, when the metal electrode layer 140 has been negatively electrified and an appropriate bias is applied to the impurity regions 102, holes from the substrate 100 are trapped into the trap sites of the silicon nitride layer 120 functioning as the charge trapping layer. As a result, the trapped holes are recombined with electrons already present in the trap sites. This operation is an erasing operation.

However, nonvolatile memory devices having such a MANOS structure exhibit a drawback of a low erase speed, as compared to the stacked floating gate structure. In order to overcome such a drawback, there has recently been an attempt to use a double-layer structure which includes a stoichiometric silicon nitride (Si₃N₄) layer having a silicon (Si)-to-nitride (N) ratio (Si/N ratio) of 3:4 as a charge trapping layer, and a silicon-rich silicon nitride layer having a Si/N ratio of 1:1 stacked over the stoichiometric silicon nitride layer. The reason why the use of the above-mentioned double-layer structure for a nonvolatile memory device is attempted is that the erase speed of the device depends on the Si/N ratio, and in detail, the higher the Si/N ratio, the faster the erase speed. However, although an increase in erase speed is achieved at a higher Si/N ratio, a degradation in retention characteristics occurs due to a trade-off between the erase speed and the retention characteristics.

### BRIEF SUMMARY OF THE INVENTION

Disclosed herein is a nonvolatile memory device that includes a substrate; a tunneling layer over the substrate; a charge trapping layer over the tunneling layer; an insulating layer over the charge trapping layer, to achieve an improvement in retention characteristics; a blocking layer over the insulating layer; and a control gate electrode over the blocking layer.

The insulating layer may include an oxide layer or a nitride layer.

The charge trapping layer may has a stacked structure that includes a stoichiometric silicon nitride layer and a silicon-rich silicon nitride layer stacked over the stoichiometric silicon nitride layer.

The insulating layer may include an oxide layer, and the charge trapping layer may have a stacked structure that includes a stoichiometric silicon nitride layer and a silicon-rich silicon nitride layer stacked over the stoichiometric silicon nitride layer, wherein the charge trapping layer has a ratio of silicon to nitride of 3:4 to 1:1.

The insulating layer may include an oxide layer, the oxide layer including a silicon oxynitride layer.

The silicon oxynitride layer may have a thickness of 1 Å to 10 Å.

The nonvolatile memory device can additionally include a second silicon oxynitride layer disposed between the tunneling layer and charge trapping layer.

The blocking layer may include an aluminum oxide layer, and the control gate electrode may include a metal layer.

The insulating layer may include a nitride layer, and the charge trapping layer has a stacked structure including a stoichiometric silicon nitride layer and a silicon-rich silicon nitride layer stacked over the stoichiometric silicon nitride layer, wherein the charge trapping layer has a ratio of silicon to nitride of 0.85:1 to 2:1.

The insulating layer may include a nitride layer, and the nitride layer may include a stoichiometric silicon nitride layer.

The stoichiometric silicon nitride layer may have a thickness of 1 Å to 10 Å.

Also disclosed herein is a method for fabricating a nonvolatile memory device. The method includes forming a tunneling layer over a substrate; forming a charge trapping layer over the tunneling layer; forming an insulating layer over the charge trapping layer to improve retention characteristics; forming a blocking layer over the insulating layer; and forming a control gate electrode over the blocking layer.

The charge trapping layer has a stacked structure that includes a stoichiometric silicon nitride layer and a silicon-rich silicon nitride layer stacked over the stoichiometric silicon nitride layer.

The insulating layer may have a thickness of 1 Å to 10 Å.

The step of forming the insulating layer may include performing an oxidation process for an upper portion of the charge trapping layer, thereby forming an oxide layer.

The oxidation process may include performing rapid thermal processing in an oxygen (O₂) atmosphere at a temperature of about 600° C. to 950° C. for about 10 seconds to 60 seconds.

The step of forming the insulating layer can include performing a nitration process for an upper portion of the charge trapping layer, thereby forming a stoichiometric silicon nitride layer.

The nitration process may include performing rapid thermal processing in an ammonia (NH₃) atmosphere at a temperature of about 600° C. to 950° C. for about 10 seconds to 60 seconds, and performing rapid thermal processing in a vacuum nitrogen (N₂) atmosphere at a temperature of about 600° C. to 950° C. for about 10 seconds to 60 seconds, thereby achieving a surface stabilization.

The nitration process may include performing a plasma nitration method.

The blocking layer may include an aluminum oxide layer, and the control gate electrode may include a metal layer.

The method can further include forming a first silicon oxynitride layer over the tunneling layer before the step of forming the charge trapping layer; wherein the charge trapping layer includes a silicon nitride layer and the insulating layer includes a second silicon oxynitride layer.

### BRIEF DESCRIPTION OF THE DRAWINGS

FIG. 1 is a sectional view illustrating a nonvolatile memory device having a general metal-alumina-nitride-oxide-silicon (MANOS) structure.

FIG. 2 is a sectional view illustrating a nonvolatile memory device according to an embodiment of the invention.

FIGS. 3A and 3B are graphs depicting the results of an atomic emission spectroscopy (AES) performed to identify and quantify the atoms in a charge trapping layer of the nonvolatile memory device according to the illustrated embodiment of the invention and in a charge trapping layer of a conventional nonvolatile memory device, respectively.

FIGS. 4 to 6 are sectional views illustrating a method for fabricating the nonvolatile memory device of FIG. 2.

FIG. 7 is a sectional view illustrating a nonvolatile memory device according to another embodiment of the invention.

FIGS. 8 to 10 are sectional views illustrating a method for fabricating the nonvolatile memory device of FIG. 7.

FIGS. 11A to 11C are graphs depicting the results of an X-ray photoelectron spectroscopy (XPS) performed to analyze the kinds and amounts of atoms in a charge trapping layer of the nonvolatile memory device according to the illustrated embodiment of the present invention and in a charge trapping layer of a conventional nonvolatile memory device, respectively.

FIG. 12 is a sectional view illustrating a nonvolatile memory device according to another embodiment of the present invention.

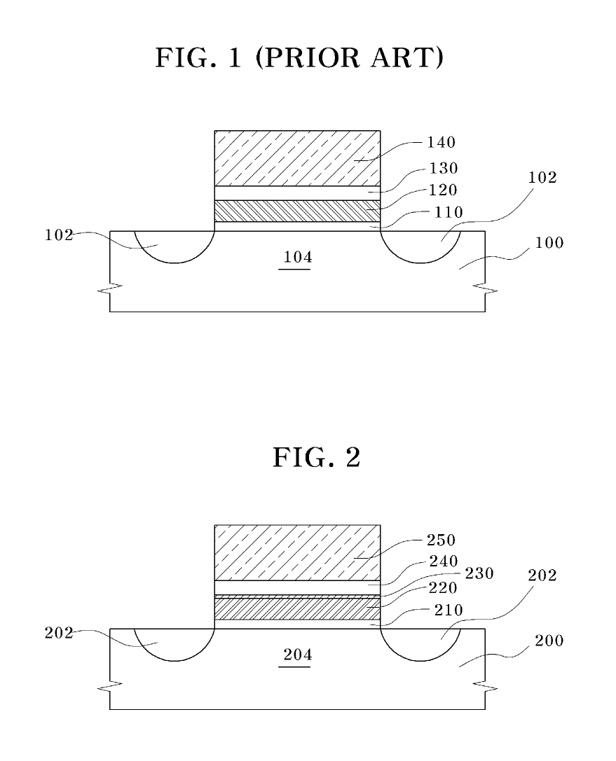

### DETAILED DESCRIPTION OF THE INVENTION

FIG. 2 is a sectional view illustrating a nonvolatile memory device according to an embodiment of the invention. Referring to FIG. 2, the nonvolatile memory device according to the illustrated embodiment includes a substrate 200. The nonvolatile memory device also includes a tunneling layer 210, a charge trapping layer 220, an oxide layer 230 (i.e., an insulating layer) for an improvement in retention characteristics, a blocking layer 240, and a control gate electrode 250, which are arranged over the substrate 200 in the recited order. The substrate 200 has impurity regions 202 disposed to be spaced apart from each other by a channel region 204. The substrate 200 may be a silicon substrate. If necessary, for the substrate 200, a substrate other than the silicon substrate, for example, a silicon-on-insulator (SOI) substrate, may be used. The impurity regions 202 are typically source/drain regions. The tunneling layer 210 is an insulating layer. Through this insulating layer, charge carriers such as electrons or holes may be injected into the charge trapping layer 220 under a certain condition. A silicon oxide (SiO₂) layer is preferably used as the tunneling layer 210. In this case, the silicon oxide layer has a thickness of about 20 Å to 60 Å. When the silicon oxide layer is excessively thin, it may be degraded by repeated tunneling of charge carriers, thereby causing a degradation in the stability of the device. On the other hand, when the silicon oxide layer is excessively thick, the tunneling of charge carriers may not be performed smoothly.

The charge trapping layer 220 is an insulating layer functioning to trap the electrons or holes injected through the tunneling layer 210. The charge trapping layer 220 preferably includes a silicon nitride layer having a silicon (Si)-to-nitride (N) ratio (Si/N ratio) of 3:4 to 1:1. When the silicon nitride layer is used, the charge trapping layer 220 may have a double-layer structure including a stoichiometric silicon nitride layer and a silicon-rich silicon nitride layer stacked over the stoichiometric silicon nitride layer. The charge trapping layer 220 preferably has a thickness of about 40 Å to 120 Å. Although there is no inter-silicon combination in the stoichiometric silicon nitride layer, there is an inter-silicon combination in the silicon-rich silicon nitride layer. As a result, hole trapping can be relatively easily generated in the charge trapping layer 220 having the above-described structure. Accordingly, the removal speed for the trapped electrons is high. Also, an increase in erase speed can be achieved in accordance with the hole trapping. In addition, a sufficiently low threshold voltage distribution can be exhibited after the erasing operation.

The oxide layer 230 for improved retention characteristics is adapted to compensate for degraded retention characteristics resulting from the increase in the Si/N ratio of the charge trapping layer 220. The oxide layer 230 may be formed by oxidizing the upper portion of the charge trapping layer 220 to a certain thickness. In this case, the oxide layer 230 preferably includes a silicon oxynitride (SiOₓN_{y}) layer. Preferably, “x” and “y” are each individually about 1 (i.e. the ratio of oxygen to silicon and nitrogen to silicon in SiOₓN_{y} are about 1:1) and the ratio of x:y is also preferably about 1:1. In this case, the silicon oxynitride layer preferably has a thickness of about 1 Å to 10 Å. The silicon oxynitride layer reduces the Coulomb repulsion among trapped charges, and thus suppresses charge trapping at the boundaries thereof and compensates for silicon dangling bonds, thereby suppressing a degradation in retention characteristics. Thus, as used herein, an improvement in retention characteristics refers to any combination of the following effects: a reduction in Coulomb repulsion among trapped charges, a suppression of charge trapping at the interface between the charge trapping layer and the insulating layer, and/or a compensation for dangling silicon bonds.

The blocking layer 240 is an insulating layer for cutting off the movement of charges between the charge trapping layer 220 and the control gate electrode 250. The blocking layer 240 preferably includes a silicon oxide (SiO₂) layer (e.g., deposited in accordance with a chemical vapor deposition (CVD) method) or an aluminum oxide (Al₂O₃) layer. If necessary, the blocking layer 240 can include an insulating layer having a high dielectric constant (i.e., other than the aluminum oxide layer) for example, a hafnium oxide (HfO₂) layer, a hafnium aluminum oxide (HfAlO) layer, a zirconium oxide (ZrO₂) layer, or a combination thereof. When the aluminum oxide layer is used for the blocking layer 240, it preferably has a thickness of about 50 Å to 300 Å.

The control gate electrode 250 functions to trap electrons or holes in the channel region 204 to the trap sites of the charge trapping layer 220. For this trapping function, a bias having a certain level is applied to the control gate electrode 250. The control gate electrode 250 is preferably either a polysilicon layer or a metal layer. When a metal layer is used as the control gate electrode 250, the metal layer can include a metal layer having a work function of about 4.5 eV or more, for example, a titanium nitride (TiN) layer, a tantalum nitride (TaN) layer, a hafnium nitride (HfN) layer, a tungsten nitride (WN) layer, or a combination thereof. In a further embodiment, a low-resistance layer (not shown) may be disposed over the control gate electrode 250 to reduce the resistance of a control gate line. The low-resistance layer material can be selected depending on the material of the control gate electrode 250. The low-resistance layer material depends on the level of reaction generated at the interface between the control gate electrode 250 and the low-resistance layer.

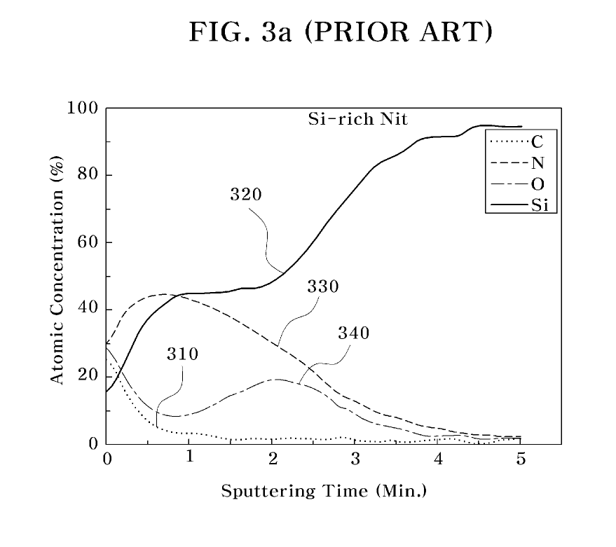

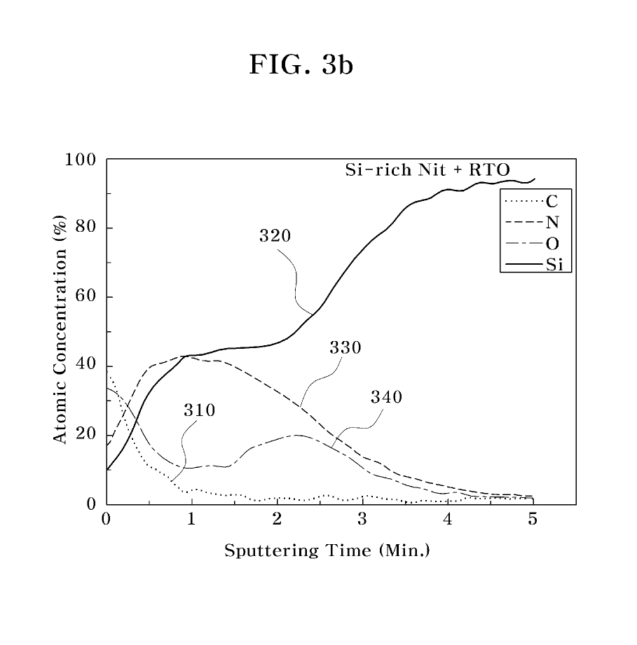

FIGS. 3A and 3B are graphs depicting the results of an atomic emission spectroscopy (AES) performed to identify and quantify the atoms in the charge trapping layer of the nonvolatile memory device according to the illustrated embodiment of the invention (FIG. 3A) and in the charge trapping layer of a conventional nonvolatile memory device (FIG. 3B), respectively. In FIGS. 3A and 3B, the horizontal axis represents a sputter time, and the vertical axis represents an atomic concentration. The line designated by reference numeral “310” represents a variation in the concentration of carbon (C) atoms. The line designated by reference numeral “320” represents a variation in the concentration of silicon (Si) atoms. The line designated by reference numeral “330” represents a variation in the concentration of nitride (N) atoms. The line designated by reference numeral “340” represents a variation in the concentration of oxygen (O) atoms. Referring to a variation in the concentration of oxygen atoms (see the line 340) in FIGS. 3A and 3B, it can be seen that the concentration of oxygen atoms exhibited during a sputtering time of about 1 to 2 minutes in the invention is higher than that of the conventional case. Accordingly, it can be seen that an improvement in retention characteristics is achieved.

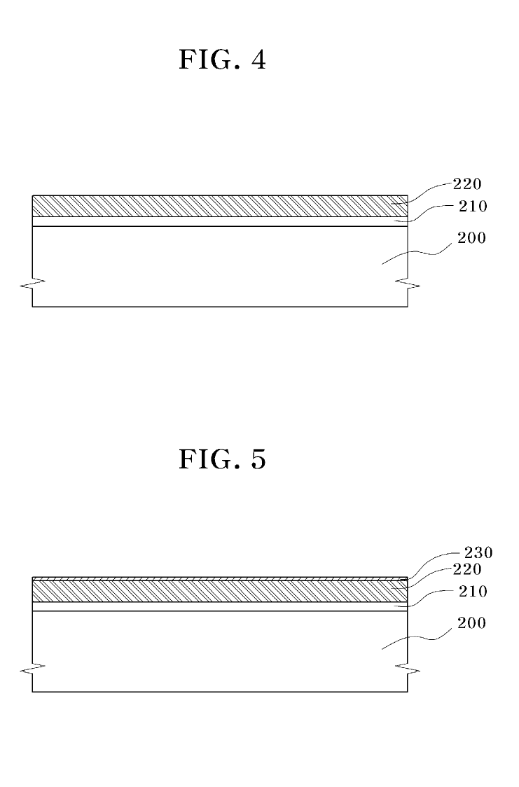

FIGS. 4 to 6 are sectional views illustrating a method for fabricating the nonvolatile memory device of FIG. 2. As shown in FIG. 4, a tunneling layer 210 is first formed over a substrate 200 which may be, for example, a silicon substrate. The tunneling layer 210 may be formed of a silicon oxide layer having a thickness of about 20 Å to 60 Å. Thereafter, a charge trapping layer 220 is formed over the tunneling layer 210. The charge trapping layer 220 preferably has a thickness of about 40 Å to 120 Å. The charge trapping layer 220 also preferably includes a Si/N layer having a Si/N ratio of 3:4 to 1:1. For this Si/N ratio, the charge trapping layer 220 can be formed to have a single-layer structure of a silicon-rich silicon nitride layer or a stacked structure including a stoichiometric silicon nitride layer and a silicon-rich silicon nitride layer stacked over the stoichiometric silicon nitride layer. The charge trapping layer 220 is preferably formed using an atomic layer deposition (ALD) method or a chemical vapor deposition (CVD) method. In this case, the Si/N ratio of the charge trapping layer 220 is controlled by varying the supply amounts of dichlorosilane (DCS) or silane (SiH₄) as a source gas for silicon and ammonia (NH₃) gas as a source gas for nitrogen.

Next, as shown in FIG. 5, an oxidation process is performed on the surface of the charge trapping layer 220 to form an oxide layer 230 to improve the retention characteristics of the charge trapping layer 220. For the oxidation process, rapid thermal processing (RTP) is preferably performed in an oxygen (O₂) atmosphere at a temperature of about 600° C. to 950° C. for about 10 seconds to 60 seconds. When the charge trapping layer 220 includes a silicon nitride layer, the resulting oxide layer 230 includes silicon oxynitride (SiOₓN_{y}). In this case, the silicon oxynitride layer preferably has a thickness of about 1 Å to 10 Å.

Thereafter, as shown in FIG. 6, a blocking layer 240 is formed over the oxide layer 230. The blocking layer 240 preferably includes an aluminum oxide (Al₂O₃) layer having a thickness of about 50 Å to 300 Å. In this case, rapid thermal processing is carried out after the deposition of the aluminum oxide layer, in order to densify the aluminum oxide layer. If necessary, the blocking layer 240 may be formed of a high-k dielectric layer, in place of the aluminum oxide layer. Alternatively, a silicon oxide layer formed using a CVD method may be used for the blocking layer 240. A control gate electrode 250 is then formed over the blocking layer 240. If necessary, a low-resistance layer is formed over the control gate electrode 250. The control gate electrode 250 preferably includes a metal layer. However, if necessary, the control gate electrode 250 can include a polysilicon layer. When the control gate electrode 250 is formed of a metal layer, a layer made of a metal material having a work function of about 4.5 eV, for example, a titanium nitride (TiN) or a tantalum nitride (TaN) layer, may be used for the metal layer. If necessary, in order to reduce the specific resistance of the control gate, a polysilicon/tungsten silicide layer or a tungsten nitride/tungsten layer may be deposited over the titanium nitride layer or tantalum nitride layer.

After the formation of the control gate electrode 250, general gate stack patterning is carried out to form a gate stack. The gate stack patterning may be carried out using a hard mask pattern (not shown). Portions of the substrate 200, on which source/drain regions are to be formed, are exposed through the gate stack. Thereafter, general ion implementation is carried out to form the source/drain regions 202 in the substrate 200.

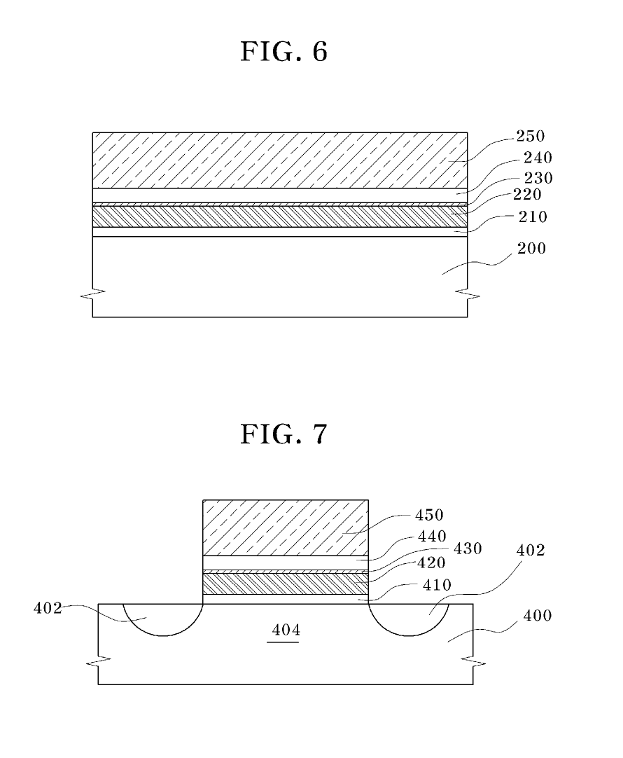

FIG. 7 is a sectional view illustrating a nonvolatile memory device according to another embodiment of the present invention. Referring to FIG. 7, the nonvolatile memory device according to this embodiment includes a substrate 400. The nonvolatile memory device also includes a tunneling layer 410, a charge trapping layer 420, a nitride layer 430 (i.e., an insulating layer) for an improvement in retention characteristics, a blocking layer 440, and a control gate electrode 450, which are disposed over the substrate 400 in the recited order. The substrate 400 has impurity regions 402 disposed to be spaced apart from each other by a channel region 404. The substrate 400 may be a silicon substrate. If necessary, the substrate 400 can also be a silicon-on-insulator (SOI) substrate. The impurity regions 402 are typically source/drain regions. The tunneling layer 410 is an insulating layer. Through this insulating layer, charge carriers such as electrons or holes may be injected into the charge trapping layer 420 under a certain condition. For the tunneling layer 410, a silicon oxide (SiO₂) layer is preferably used. In this case, the silicon oxide layer has a thickness of about 20 Å to 60 Å. When the silicon oxide layer is excessively thin, it may be degraded by repeated tunneling of charge carriers, thereby causing a degradation in the stability of the device. On the other hand, when the silicon oxide layer is excessively thick, the tunneling of charge carriers may not be performed smoothly.

The charge trapping layer 420 is an insulating layer functioning to trap the electrons or holes injected through the tunneling layer 410. The charge trapping layer 420 preferably includes a silicon nitride layer having a silicon (Si)-to-nitride (N) ratio (Si/N ratio) of 0.85:1 to 2:1. In this case, the charge trapping layer 420 may have a double-layer structure including a stoichiometric silicon nitride layer and a silicon-rich silicon nitride layer stacked over the stoichiometric silicon nitride layer. The charge trapping layer 420 preferably has a thickness of about 40 Å to 120 Å. Although there is no inter-silicon combination in the stoichiometric silicon nitride layer, there is an inter-silicon combination in the silicon-rich silicon nitride layer. As a result, hole trapping can be relatively easily generated in the charge trapping layer 420 having the above-described structure. Accordingly, the removal speed for the trapped electrons is high. Also, an increase in erase speed can be achieved in accordance with the hole trapping. In addition, a sufficiently low threshold voltage distribution can be exhibited after the erasing operation.

The nitride layer 430 for improved retention characteristics is adapted to compensate for degraded retention characteristics resulting from the increase in the Si/N ratio of the charge trapping layer 420. The nitride layer 430 may be formed by nitrating the upper portion of the charge trapping layer 420 to a certain thickness. The nitride layer 430 preferably includes a stoichiometric silicon nitride (Si₃N₄) layer. In this case, the stoichiometric silicon nitride layer has a thickness of about 1 Å to 10 Å. The stoichiometric silicon nitride layer compensates for degraded retention characteristics caused by the charge trapping layer 420 which has a high Si/N ratio.

The blocking layer 440 is an insulating layer for cutting off the movement of charges between the charge trapping layer 420 and the control gate electrode 450. The blocking layer 440 preferably includes a silicon oxide (SiO₂) layer deposited in accordance with a chemical vapor deposition (CVD) method, or an aluminum oxide (Al₂O₃) layer. If necessary, the blocking layer 440 can include an insulating layer having a high dielectric constant, other than the aluminum oxide layer, for example, a hafnium oxide (HfO₂) layer, a hafnium aluminum oxide (HfAlO) layer, a zirconium oxide (ZrO₂) layer, or a combination thereof. When the aluminum oxide layer is used for the blocking layer 440, it preferably has a thickness of about 50 Å to 300 Å.

The control gate electrode 450 functions to trap electrons or holes in the channel region 404 to the trap sites of the charge trapping layer 420. For this trapping function, a bias having a certain level is applied to the control gate electrode 450. The control gate electrode 450 is preferably either a polysilicon layer or a metal layer. When a metal layer is used as the control gate electrode 450, the metal layer can include a metal layer having a work function of about 4.5 eV or more, for example, a titanium nitride (TiN) layer, a tantalum nitride (TaN) layer, a hafnium nitride (HfN) layer, a tungsten nitride (WN) layer, or a combination thereof. In a further embodiment, a low-resistance layer (not shown) may be arranged over the control gate electrode 450, to reduce the resistance of a control gate line. The low-resistance layer material can be selected depending on the material of the control gate electrode 450. The low-resistance layer material depends on the level of reaction generated at the interface between the control gate electrode 450 and the low-resistance layer.

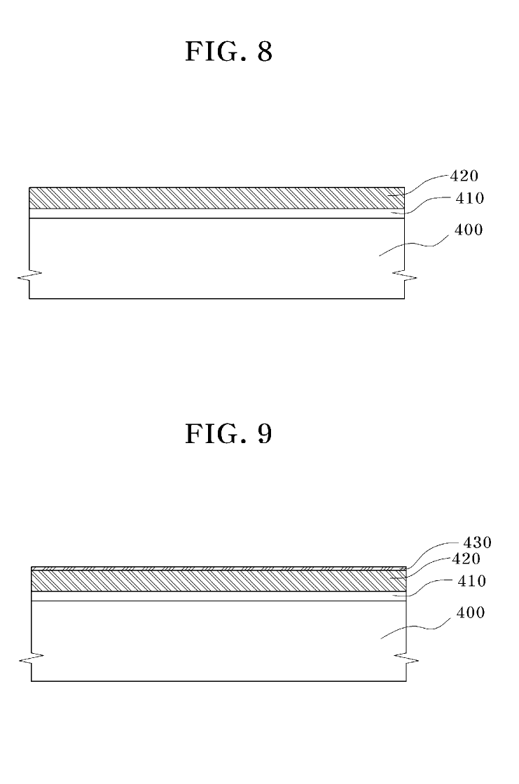

FIGS. 8 to 10 are sectional views illustrating a method for fabricating the nonvolatile memory device of FIG. 7. As shown in FIG. 8, a tunneling layer 410 is first formed over a substrate 400 which may be, for example, a silicon substrate. The tunneling layer 410 may be formed of a silicon oxide layer having a thickness of about 20 Å to 60 Å. Thereafter, a charge trapping layer 420 is formed over the tunneling layer 410. The charge trapping layer 420 preferably has a thickness of about 40 Å to 120 Å. The charge trapping layer 420 preferably also has a Si/N ratio of 0.85:1 to 2:1. For this Si/N ratio, the charge trapping layer 420 can be formed to have a single-layer structure of a silicon-rich silicon nitride layer or a stacked structure including a stoichiometric silicon nitride layer and a silicon-rich silicon nitride layer stacked over the stoichiometric silicon nitride layer. The charge trapping layer 420 is preferably formed using an atomic layer deposition (ALD) method or a chemical vapor deposition (CVD) method.

Next, as shown in FIG. 9, an nitration process is performed on the surface of the charge trapping layer 420, to form a nitride layer 430 to improve the retention characteristics of the charge trapping layer 420. For the nitration process, rapid thermal processing (RTP) is preferably performed in an ammonia (NH₃) atmosphere at a temperature of about 600° C. to 950° C. for about 10 seconds to 60 seconds. After the rapid thermal processing, additional rapid thermal processing is carried out in a vacuum nitrogen (N₂) atmosphere under the same temperature and time conditions as those of the previous rapid thermal processing, in order to stabilize the surface of the nitride layer 430. When the charge trapping layer 420 includes a stoichiometric silicon nitride layer, the nitride layer 430 preferably includes silicon nitride (Si₃N₄). In this case, the stoichiometric silicon nitride layer has a thickness of about 1 Å to 10 Å.

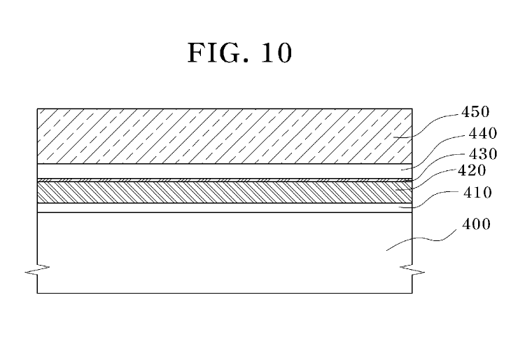

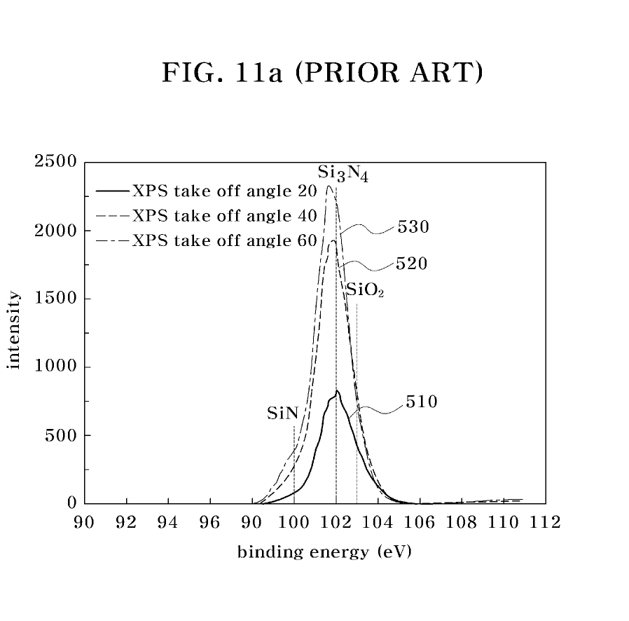

Thereafter, as shown in FIG. 10, a blocking layer 440 is formed over the nitride layer 430. The blocking layer 440 preferably includes an aluminum oxide (Al₂O₃) layer having a thickness of about 50 Å to 300 Å. In this case, rapid thermal processing is carried out after the deposition of the aluminum oxide layer, in order to densify the aluminum oxide layer. If necessary, the blocking layer 440 may be formed of a high-k dielectric layer, in place of the aluminum oxide layer. Alternatively, a silicon oxide layer formed using a CVD method may be used for the blocking layer 440. A control gate electrode 450 is then formed over the blocking layer 440. If necessary, a low-resistance layer is formed over the control gate electrode 450. The control gate electrode 450 preferably includes a metal layer. However, if necessary, the control gate electrode 450 can include a polysilicon layer. When the control gate electrode 450 is formed of a metal layer, a layer made of a metal material having a work function of about 4.5 eV, for example, a titanium nitride (TiN) or a tantalum nitride (TaN) layer, may be used for the metal layer. If necessary, in order to reduce the specific resistance of the control gate, a polysilicon/tungsten silicide layer or a tungsten nitride/tungsten layer may be deposited over the titanium nitride layer or tantalum nitride layer.

After the formation of the control gate electrode 450, general gate stack patterning is carried out to form a gate stack. The gate stack patterning may be carried out using a hard mask pattern (not shown). Portions of the substrate 400, on which source/drain regions are to be formed, are exposed through the gate stack. Thereafter, general ion implementation is carried out to form the source/drain regions 402 in the substrate 400.

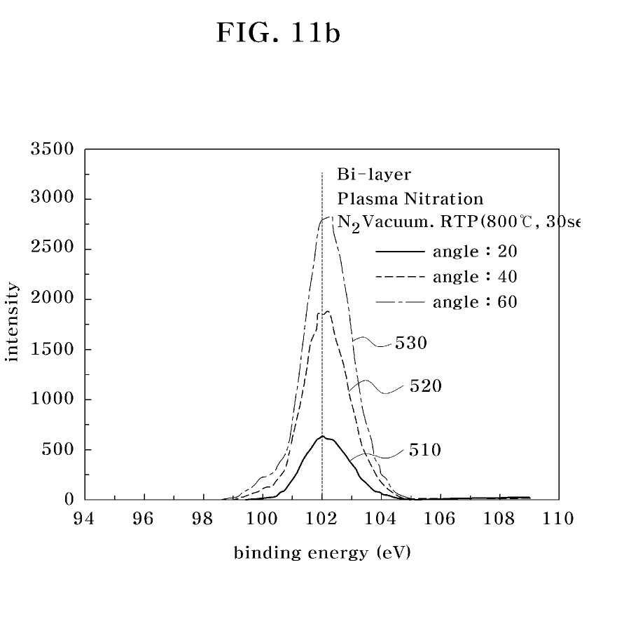

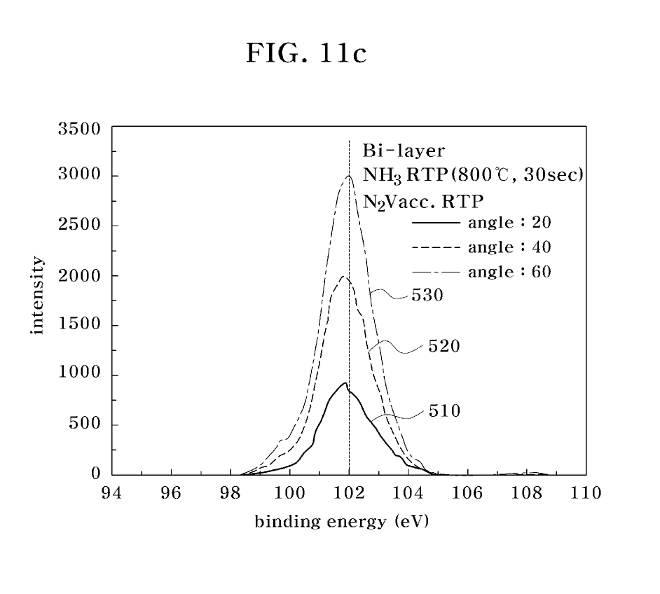

FIGS. 11A to 11C are graphs depicting the results of an X-ray photoelectron spectroscopy (XPS) performed to analyze the kinds and amounts of atoms in the charge trapping layer of nonvolatile memory devices according to an embodiment of the invention and in the charge trapping layer of a conventional nonvolatile memory device. FIG. 11A is a graph associated with the conventional nonvolatile memory device. FIGS. 11B and 11C are graphs associated with the nonvolatile memory devices according to the invention. In particular, FIG. 11B depicts results obtained when a plasma nitration method was performed, and FIG. 11C depicts results obtained when rapid thermal processing was performed for the nitration method. In FIGS. 11A to 11C, the horizontal axis represents binding energy, whereas the vertical axis represents intensity. Also, the line designated by reference numeral “510” represents a distribution of silicon nitride. The line designated by reference numeral “520” represents a distribution of a silicon oxide layer. The line designated by reference numeral “530” represents a distribution of a stoichiometric silicon nitride layer. After comparison of the stoichiometric silicon nitride layer distribution (see the line 530) in FIG. 11A and the stoichiometric silicon nitride layer distribution (see the line 530) in FIG. 11B or 11C, it can be seen that the stoichiometric silicon nitride is exhibited in a relatively large amount in embodiments of the invention, in which a surface nitration process was carried out, as compared to the conventional case. Accordingly, it can be seen that an improvement in retention characteristics is achieved.

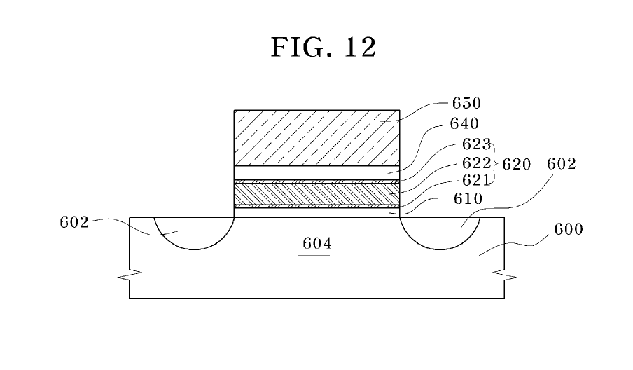

FIG. 12 is a sectional view illustrating a nonvolatile memory device according to another embodiment of the present invention. Referring to FIG. 12, the nonvolatile memory device according to this embodiment includes a substrate 600. The nonvolatile memory device also includes a tunneling layer 610, a charge trapping layer 620, a blocking layer 640, and a control gate electrode 650, which are disposed over the substrate 600 in this order. The substrate 600 has impurity regions 602 disposed to be spaced apart from each other by a channel region 604. The substrate 600 is preferably a silicon substrate, but it can also be, for example, a silicon-on-insulator (SOI) substrate. The impurity regions 602 are typically source/drain regions.

The tunneling layer 610 is an insulating layer. Through this insulating layer, charge carriers such as electrons or holes may be injected into the charge trapping layer 620 under a certain condition. For the tunneling layer 610, a silicon oxide (SiO₂) layer is preferably used. In this case, the silicon oxide layer has a thickness of about 20 Å to 60 Å. When the silicon oxide layer is excessively thin, it may be degraded by repeated tunneling of charge carriers, thereby causing a degradation in the stability of the device. On the other hand, when the silicon oxide layer is excessively thick, the tunneling of charge carriers may not be performed smoothly.

The charge trapping layer 620 is an insulating layer functioning to trap the electrons or holes injected through the tunneling layer 610. The charge trapping layer 620 includes a lower silicon oxynitride (SiOₓN_{y}) layer 621 preferably having a thickness of about 5 Å to 30 Å, a silicon nitride layer 622 preferably having a thickness of about 20 Å to 100 Å, and an upper silicon oxynitride (SiOₓN_{y}) layer 623 preferably having a thickness of about 5 Å to 30 Å. The silicon nitride layer 622 may be a stoichiometric silicon nitride layer or a silicon-rich silicon nitride layer. Each of the lower and upper silicon oxynitride layers 621 and 623 may be a nitride-rich (N-rich) silicon oxynitride (SiOₓN_{y}) layer. Preferably, “x” and “y” are each individually about 1 (i.e. the ratio of oxygen to silicon and nitrogen to silicon in SiOₓN_{y} are about 1:1) and the ratio of x:y is also preferably about 1:1. The silicon oxynitride layer has a high dielectric constant and characteristics resistant to a high electric field and hot carrier stress, as compared to general silicon oxide layers. Accordingly, the silicon oxynitride layer can reduce trapping and leakage phenomena at the boundary thereof with the blocking layer 640, and thus can achieve an improvement in retention characteristics.

The blocking layer 640 is an insulating layer for cutting off the movement of charges between the charge trapping layer 620 and the control gate electrode 650. The blocking layer 640 preferably includes a silicon oxide (SiO₂) layer deposited in accordance with a chemical vapor deposition (CVD) method, or an aluminum oxide (Al₂O₃) layer. If necessary, the blocking layer 640 can include an insulating layer having a high dielectric constant, other than the aluminum oxide layer, for example, a hafnium oxide (HfO₂) layer, a hafnium aluminum oxide (HfAlO) layer, a zirconium oxide (ZrO₂) layer, or a combination thereof. When the aluminum oxide layer is used for the blocking layer 640, it has a thickness of about 50 Å to 300 Å.

The control gate electrode 650 functions to trap electrons or holes in the channel region 604 to the trap sites of the charge trapping layer 620. For this trapping function, a bias having a certain level is applied to the control gate electrode 650. The control gate electrode 650 is preferably either a polysilicon layer or a metal layer. When a metal layer is used as the control gate electrode 650, the metal layer can include a metal layer having a work function of about 4.5 eV or more, for example, a titanium nitride (TiN) layer, a tantalum nitride (TaN) layer, a hafnium nitride (HfN) layer, a tungsten nitride (WN) layer, or a combination thereof. In a further embodiment, a low-resistance layer (not shown) may be arranged over the control gate electrode 650 to reduce the resistance of a control gate line. The low-resistance layer material can be selected depending on the material of the control gate electrode 650. The low-resistance layer material depends on the level of reaction generated at the interface between the control gate electrode 650 and the low-resistance layer.

In order to fabricate the above-described nonvolatile memory device, a tunneling layer 610 is first formed over a substrate 600 which may be, for example, a silicon substrate. The tunneling layer 610 may be formed of a silicon oxide layer having a thickness of about 20 Å to 60 Å. Thereafter, a charge trapping layer 620 is formed over the tunneling layer 610. In order to form the charge trapping layer 620, a lower nitride-rich silicon oxynitride layer 621 is first formed to a thickness of about 5 Å to 30 Å, using an atomic layer deposition (ALD) method or a chemical vapor deposition (CVD) method. Upon forming the lower nitride-rich silicon oxynitride (SiOₓN_{y}) layer, the values of “x” and “y” are each controlled to be about 1. Next, a silicon nitride layer 622 is formed to a thickness of about 20 Å to 100 Å over the lower nitride-rich silicon oxynitride layer 621, using an ALD method or a CVD method. The silicon nitride layer 622 is formed of a stoichiometric silicon nitride layer or a silicon-rich silicon nitride layer. In this case, in order to control the silicon/nitride ratio of the silicon nitride layer 622 to be 3:4 to 1:1, the supply amounts of DCS or SiH₄ as a source gas for silicon and NH₃ gas as a source gas for nitride are controlled. Thereafter, an upper nitride-rich silicon oxynitride layer 623 is formed over the silicon nitride layer 622. The upper nitride-rich silicon oxynitride layer 623 is formed to a thickness of about 5 Å to 30 Å, using an ALD method or a CVD method. Upon forming the upper nitride-rich silicon oxynitride (SiOₓN_{y}) layer, the values of “x” and “y” are controlled to be about 1.

Thereafter, a blocking layer 640 is formed over the charge trapping layer 620. The blocking layer 640 preferably includes an aluminum oxide (Al₂O₃) layer having a thickness of about 50 Å to 300 Å. In this case, rapid thermal processing is carried out after the deposition of the aluminum oxide layer, in order to densify the aluminum oxide layer. If necessary, the blocking layer 640 may be formed of a high-k dielectric layer, in place of the aluminum oxide layer. Alternatively, an oxide layer formed using a CVD method may be used for the blocking layer 640. A control gate electrode 650 is then formed over the blocking layer 640. If necessary, a low-resistance layer is formed over the control gate electrode 650. The control gate electrode 650 preferably includes of a metal layer. However, if necessary, the control gate electrode 650 can be formed of a polysilicon layer. When the control gate electrode 650 is formed of a metal layer, a layer made of a metal material having a work function of about 4.5 eV, for example, a titanium nitride (TiN) or a tantalum nitride (TaN) layer, may be used for the metal layer. If necessary, in order to reduce the specific resistance of the control gate, a polysilicon/tungsten silicide layer or a tungsten nitride/tungsten layer may be deposited over the titanium nitride layer or tantalum nitride layer. After the formation of the control gate electrode 650, general gate stack patterning is carried out to form a gate stack. The gate stack patterning may be carried out using a hard mask pattern (not shown). Portions of the substrate 600, on which source/drain regions are to be formed, are exposed through the gate stack. Thereafter, general ion implementation is carried out to form the source/drain regions in the substrate 600.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A nonvolatile memory device comprising:
a substrate;
a tunneling layer formed over the substrate;
a charge trapping layer formed over the tunneling layer;
an insulating layer formed over the charge trapping layer for improving retention characteristics of the charge trapping layer;
a blocking layer formed over the insulating layer; and
a control gate electrode formed over the blocking layer.

2. The nonvolatile memory device according to claim 1, wherein the insulating layer comprises an oxide layer or a nitride layer.

3. The nonvolatile memory device according to claim 1, wherein the charge trapping layer has a stacked structure comprising a stoichiometric silicon nitride layer and a silicon-rich silicon nitride layer stacked over the stoichiometric silicon nitride layer.

4. The nonvolatile memory device according to claim 1, wherein the insulating layer comprises an oxide layer, and the charge trapping layer has a stacked structure comprising a stoichiometric silicon nitride layer and a silicon-rich silicon nitride layer stacked over the stoichiometric silicon nitride layer, wherein the charge trapping layer has a ratio of silicon to nitride of 3:4 to 1:1.

5. The nonvolatile memory device according to claim 1, wherein the insulating layer comprises an oxide layer, the oxide layer comprising a silicon oxynitride layer.

6. The nonvolatile memory device according to claim 5, wherein the silicon oxynitride layer has a thickness of 1 Å to 10 Å.

7. The nonvolatile memory device according to claim 5, further comprising a second silicon oxynitride layer disposed between the tunneling layer and charge trapping layer.

8. The nonvolatile memory device according to claim 1, wherein the blocking layer comprises an aluminum oxide layer, and the control gate electrode comprises a metal layer.

9. The nonvolatile memory device according to claim 1, wherein the insulating layer comprises a nitride layer, and the charge trapping layer has a stacked structure comprising a stoichiometric silicon nitride layer and a silicon-rich silicon nitride layer stacked over the stoichiometric silicon nitride layer, wherein the charge trapping layer has a ratio of silicon to nitride of 0:85:1 to 2:1.

10. The nonvolatile memory device according to claim 1, wherein the insulating layer comprises a nitride layer, the nitride layer comprising a stoichiometric silicon nitride layer.

11. The nonvolatile memory device according to claim 10, wherein the stoichiometric silicon nitride layer has a thickness of 1 Å to 10 Å.

12. A nonvolatile memory device comprising:
a substrate;
a tunneling layer formed over the substrate;
a charge trapping layer formed over the tunneling layer;
an oxide layer formed over the charge trapping layer for improving retention characteristics of the charge trapping layer;
a blocking layer formed over the insulating layer; and
a control gate electrode formed over the blocking layer.

13. A nonvolatile memory device comprising:
a substrate;
a tunneling layer formed over the substrate;
a charge trapping layer formed over the tunneling layer;
a nitride layer formed over the charge trapping layer for improving retention characteristics of the charge trapping layer;
a blocking layer formed over the insulating layer; and
a control gate electrode formed over the blocking layer.

14. A method for fabricating a nonvolatile memory device, comprising:
forming a tunneling layer over a substrate;
forming a charge trapping layer over the tunneling layer;
forming an insulating layer over the charge trapping layer for improving retention characteristics of the charge trapping layer;
forming a blocking layer over the insulating layer; and
forming a control gate electrode over the blocking layer.

15. The method according to claim 14, wherein the charge trapping layer has a stacked structure comprising a stoichiometric silicon nitride layer and a silicon-rich silicon nitride layer stacked over the stoichiometric silicon nitride layer.

16. The method according to claim 14, wherein the insulating layer has a thickness of 1 Å to 10 Å.

17. The method according to claim 14, wherein the step of forming the insulating layer comprises performing an oxidation process for an upper portion of the charge trapping layer to form an oxide layer.

18. The method according to claim 17, wherein the oxidation process comprises performing rapid thermal processing in an oxygen (O₂) atmosphere at a temperature of about 600° C. to 950° C. for about 10 seconds to 60 seconds.

19. The method according to claim 14, wherein the step of forming the insulating layer comprises performing a nitration process on an upper portion of the charge trapping layer to form a stoichiometric silicon layer.

20. The method according to claim 19, wherein the nitration process comprises:
performing rapid thermal processing in an ammonia (NH₃) atmosphere at a temperature of about 600° C. to 950° C. for about 10 seconds to 60 seconds; and
performing rapid thermal processing in a vacuum nitrogen (N₂) atmosphere at a temperature of about 600° C. to 950° C. for about 10 seconds to 60 seconds to achieve a surface stabilization.

21. The method according to claim 19, wherein the nitration process comprises performing a plasma nitration method.

22. The method according to claim 14, wherein the blocking layer comprises an aluminum oxide layer, and the control gate electrode comprises a metal layer.

23. The method of claim 14, further comprising: forming a first silicon oxynitride layer over the tunneling layer and before the step of forming the charge trapping layer;
wherein:
the charge trapping layer comprises a silicon nitride layer; and,
the insulating layer comprises a second silicon oxynitride layer.
